(19) United States
(12) Patent Application Publication
(10) Pub. No.: US 2011/0147784 A1
(43) Pub. Date: Jun. 23, 2011

(54) Light emitting device with more uniform current spreading

(75) Inventors: Michael John Brockley, Oxford (GB); Valerie Berryman-Bousquet, Middle Barton (GB)

(73) Assignee: Sharp Kabushiki Kaisha

(21) Appl. No.: 12/654,391

(22) Filed: Dec. 18, 2009

(51) Int. Cl. H01L 33/36; H01L 33/00

(52) U.S. Cl. 257/99; 257/E33.062; 257/E33.066

(57) ABSTRACT

A nitride light emitting device (LED) according to a non-limiting embodiment of the present invention may include a p-pad and an n-pad, wherein the p-pad and n-pad are disposed on opposite ends of the device. A first p-branch electrode and a second p-branch electrode may extend from the p-pad toward the n-pad, with the first p-branch electrode extending along a length of the device. The second p-branch electrode may have a bent portion so as to extend along a width and length of the device. An n-branch electrode may extend from the n-pad toward the p-pad, wherein a distal end of the n-branch electrode is angled toward the bent portion of the second p-branch electrode. Alternatively, the p-branch and n-branch electrodes may be configured such that a distance between the n-branch electrode and the first and second p-branch electrodes increases with proximity to the n-pad. As a result, the nitride-based LED according to example embodiments may exhibit improved current uniformity, lower forward operating voltage, and higher overall efficiency.

### TECHNICAL FIELD

At least one embodiment of the present invention generally relates to nitride-based light emitting devices (LEDs) and/or the design of branch electrodes for achieving more uniform current spreading and higher efficiency.

### BACKGROUND

Nitride-based LEDs are being increasingly developed for various applications (e.g., general lighting, backlighting, automotive lamps) because of their potential for relatively high light output power. However the efficiency of nitride-based LEDs still remains an obstacle for the mass adoption of the technology in the general lighting market.

FIG. 1 is a cross-sectional view of a conventional nitride-based LED. Referring to FIG. 1, the conventional nitride-based LED includes an n-type semiconductor layer 4 formed on a substrate 2. The substrate 2 may be formed of sapphire, silicon carbide, gallium nitride, or silicon. A light-emitting active region 6 is formed on the n-type semiconductor layer 4 in the vertical direction. A p-type semiconductor layer 8 is formed on the active region 6. These layers can be deposited by a variety of well-known methods, including MOVPE (metal organic vapour phase epitaxy), MBE (molecular beam epitaxy), or HVPE (hydride vapour phase epitaxy). As a result, a vertically stacked p-i-n junction is formed.

A metal n-connection pad 10 (hereafter n-pad) is formed in electrical connection with the n-type semiconductor layer 4. This is achieved by etching in part through the p-type semiconductor layer 8 and the active region 6 to expose the surface of the n-type semiconductor layer 4. The n-pad 10 has to be of a minimum size to allow an external electrical connection to the LED chip to be made. A metal n-branch electrode (or multiple n-branch electrodes) can also be formed so as to extend from the n-pad 10 while being in electrical contact with the n-type semiconductor layer 4. An n-branch electrode is essentially a thin strip of metal which extends from the n-pad 10 while being in electrical contact with the n-type semiconductor layer 4. The primary purpose of an n-branch electrode is to provide a relatively low resistance path for current to spread over the n-type semiconductor layer 4 of the device. An n-branch electrode should have a relatively small surface area because the metal absorbs light emitted by the device, thus reducing efficiency.

A transparent and electrically-conductive current spreading layer 12 is formed on the p-type semiconductor layer 8 so as to be in electrical contact with it. As a result, a relatively low resistance path for spreading current over the entire surface of the p-type semiconductor layer 8 is provided. A current spreading layer 12 is often used in nitride LEDs, because the conductivity of the p-type semiconductor layer 8 is generally much lower than that of the n-type semiconductor layer 4. The current spreading layer 12 can be made of ITO (indium tin oxide), ZnO (zinc oxide), InZnO (indium zinc oxide), or other suitable materials.

A metal p-connection pad (hereafter p-pad) 14 is formed in electrical contact with the current spreading layer 12. The p-pad 14 also has to be of a minimum physical size to allow an external electrical connection to the LED to be made. A metal p-branch electrode (or multiple p-branch electrodes) may also be formed so as to extend from the p-pad 14 while being in electrical contact with the current spreading layer 12.

It is common in conventional nitride LEDs for the sheet resistance of the n-type semiconductor layer 4 and the current spreading layer 12 to be different. This mismatch means that current will not spread uniformly throughout the active region 6 in the absence of branch electrodes. To improve the uniformity, n and p branch electrodes may be used. The branch electrodes enable the LED to operate more efficiently and at a lower voltage. The branch electrodes reduce the overall resistance path between the n-pad 10 and the p pad 14, because the branch electrodes allow current to travel much of the physical distance between the n-pad 10 and the p pad 14 in high conductivity metal and a much smaller distance in the lower conductivity p-type semiconductor layer 8, n-type semiconductor layer 4, and current spreading layer 12. The branch electrodes improve current uniformity through the active region 6, because the branch electrodes are much more conductive than the p-type semiconductor layer 8, n-type semiconductor layer 4, and current spreading layer 12. As a result, the design of the branch electrodes dominates the overall resistive path through each part of the active region 6 and determines the current distribution through the active region 6 as a whole.

Uniform current spreading is advantageous, because it prevents a phenomenon called “current crowding.” Current crowding happens when the total resistance path between the n-pad 10 and p-pad 14 is much lower through a relatively small area of the active region 6, thereby resulting in a relatively large current density through that area. This results in localized heating and reduces the efficiency of the device, because the light emission efficiency of the active region 6 decreases with temperature. A more detailed explanation of this process may be found in the description of Shockley-Read recombination in “Light-Emitting Diodes” by E. Fred Schubert (Cambridge University Press), the entire contents of which are incorporated herein by reference. Areas of relatively low current density or dark spots are also not desirable, because it does not make best use of the entire active region 6, which is relatively expensive to manufacture. The effectiveness of a branch electrode design in achieving a uniform current distribution through an LED active region 6 and reducing the forward operating voltage is relatively sensitive to the shape of the branch electrode design.

U.S. Pat. No. 6,614,056 discloses a nitride-based LED with a branch electrode design, an example of which is shown in FIG. 2. Referring to FIG. 2, the n-branch electrode 22 extends from the n-pad 18 in a straight line up the center of the chip towards the p-pad 16. First and second p-branch electrodes 20 and 21 extend from the p-pad 16 towards the opposite side of the chip to both sides of the central n-branch electrode 24. The problem with this design is that it results in a non-uniform distribution of current through the active region. In particular, it results in areas of relatively low current density (marked A in FIG. 2) in the four corners of the chip and current crowding (marked B on FIG. 2) around the ends of the p-branch electrodes 20 and 21. U.S. Pat. No. 6,614,056 also teaches keeping a uniform distance between the p-branch electrodes 20, 21 and the n-branch electrode 22. This constraint can result in current crowding and areas of relatively low current density.

U.S. Pat. No. 7,531,841 discloses a nitride-based LED with a branch electrode design with an n-electrode branch extending from the n-pad along the side of the chip not towards the p-pad. Also, two branch p-electrodes extend towards the n-pad on both sides of the center line. In one of the embodiments of this reference, the ends of the p-electrodes are inclined away from the n-pad in order to reduce current crowding around the ends of the p-electrodes. The problem with this design is that there are relatively large areas of the chip where the current density through the active region is lower than other areas of the chip: the upper corners of the chip and outside of the p-electrode. Also, the average separation between the n and p electrodes is relatively large, thereby resulting in a larger operating voltage and reducing the efficiency of the chip.

U.S. Pat. No. 6,650,018 discloses a nitride-based LED with branch electrodes where the branch electrodes are tapered along their length. The problem with this design is that it causes the contact resistance between the electrode and the semiconductor layer to increase along its length. This results in current crowding towards the base of the electrode where the contact resistance is least.

### SUMMARY

Example embodiments of the present invention relate to a nitride-based light emitting device (LED) having improved current uniformity and lower forward operating voltage. By varying the resistance path between the n and p electrodes as a function of their length according to example embodiments, the current distribution through the active region can be made more uniform across the LED chip, and the forward operating voltage may be reduced. This increases the overall light conversion efficiency of the device and reduces the electrical power consumption, thereby increasing the overall efficiency of the device.

A nitride light emitting device according to a non-limiting embodiment of the present invention may include a p-pad and an n-pad disposed on opposite ends of the device. For example, the p-pad and the n-pad may be disposed on diagonal corners of the device. A first p-branch electrode and a second p-branch electrode may extend from the p-pad toward the n-pad, with the first p-branch electrode extending along a length of the device. The second p-branch electrode may include a bent portion so as to extend along a width and length of the device. An n-branch electrode may extend from the n-pad toward the p-pad, wherein a distal end of the n-branch electrode is angled toward the bent portion of the second p-branch electrode.

A nitride light emitting device according to another non-limiting embodiment of the present invention may include a p-pad and an n-pad disposed on opposite ends of the device. A first p-branch electrode and a second p-branch electrode may extend from the p-pad toward the n-pad. An n-branch electrode may extend from the n-pad toward the p-pad, wherein a distance between the n-branch electrode and the first and second p-branch electrodes is relatively increased in relation to a relative increase in proximity to the n-pad.

According to a first, non-limiting aspect of the invention, a nitride-based LED may have a transparent current spreading layer in contact with a p-type semiconductor layer, on which there is formed a p-contact pad in one corner of the device. Extending from the p-pad are two p-branch electrodes, the first of which extends parallel to the longer edge of the chip. The second p-branch electrode extends parallel to the shorter edge of the chip and then turns to run parallel to the longer edge of the chip. The n-pad is formed on the opposite corner to the p-pad and is in contact with the n-type layer. An n-branch electrode which is in electrical contact with the n-type layer then extends diagonally for a short section until it is along the center-line of the chip, from where it extends in the direction parallel to the longer edge of the chip. The end of the electrode is inclined towards the corner opposite both the n and p contact pads and nearest the n branch electrode. This corner shall be hereafter referred to as the problem corner. The reason for this inclined n-branch electrode is to increase the current density through the active region in the problem corner. The inclination has the effect to reduce the overall resistance path for current travelling from the p to n electrode through the active region in this corner of the chip. By placing the n and p contact pads in the corners of the chip it removes the common problem of the conventional art of areas of low current density in the corners of the chip. This alone leaves one corner which still has low current density, the aforementioned problem corner. The inclined n-electrode then solves this problem, resulting in a chip with a very uniform current distribution and reduced forward operating voltage.

A second, non-limiting aspect of the invention may include a nitride-based LED having the same structure and branch electrode design as the first aspect of the invention, with an additional branch (corner extension) that is formed in the problem corner. This branch starts at the vertex of the second p-branch electrode in the problem corner and extends towards the vertex of the chip in the problem corner. This extra p-branch electrode further increases the current density through the active region in the problem corner, by reducing the resistance path for current travelling from the p-electrode branch to the n-electrode branch through the active region in the problem corner.

A third, non-limiting aspect of the invention may include a nitride-based LED having the same electrode design as described in the first aspect of the invention, with the addition that the end of the first p-branch electrode is inclined towards the n-pad. This prevents an area of low-current density from forming between the n-pad and the end of the first p-electrode by reducing the total resistance path for current to flow between the n and p electrodes through this area of active region.

A fourth, non-limiting aspect of the invention may include a nitride-based LED having the same electrode design as described in the first aspect of the invention, but instead of the p-branch electrodes extending from the p-pad separately, an extra branch of the p-electrode connects the p-pad to both branches of the original p-electrode. This has the advantage of reducing the average distance between n and p branch electrodes thus reducing the forward operating voltage of the chip. It also has the effect of introducing a slight non-uniformity to the current distribution which is advantageous in terms of the light extraction from the chip. Light generated directly under the p-pad has a lower extraction efficiency because of absorption by the metal p-pad. In order to reduce this it is advantageous to reduce the current density through the active region under the p-pad. The problem with this is that it must increase the current density in other areas of the chip and creates all the problems associated with this, which have been already discussed. There is therefore a trade-off to be made between these two effects. In this embodiment, because the current distribution through the active region was relatively uniform before the addition of the extra branch, the effect of reducing the current density underneath the p-pad has the effect of slightly increasing the average current density through the rest of the active region, but does not create any areas of current crowding, so overall the efficiency of the chip increases.

A fifth, non-limiting aspect of the invention may include a nitride-based LED having the same electrode design as described in the first aspect of the invention, with the addition that at the end of the second p-branch electrode the branch splits in two, and the two new branches (end extensions) extend from this vertex in generally opposite directions. The purpose of this extra feature is to make the end of the p-branch electrode more parallel to the edge of the n-pad that it faces. Without this feature, current would flow from all points along the edge of the n-pad to the single point at the end of the p-branch electrode, creating current crowding at the end of the p-branch electrode. With the feature, the p-branch electrode is generally parallel to the n-pad, so the resistive path between opposite points on the n-pad and the p-branch electrode is equal. This causes the current flowing out of the n-pad to flow into a larger area of p-branch electrode, thereby reducing the current crowding effect in this area of the chip. This reduces the forward operating voltage and makes chip operate more efficiently.

A sixth, non-limiting aspect of the invention may include a nitride-based based LED with a transparent current spreading in contact with a p-type layer and has an n-pad at the edge of the chip in the center of the shortest edge in contact with the n-type layer. The p-pad is then located in the center of the opposite edge of the LED, at the edge of the chip. The n-branch electrode extends from the n-pad towards the p-pad up the center line of the chip. Two p-branch electrodes extend from the p-pad towards the opposite edge along both sides of the central branch n-electrode. The distance between the n and p branch electrodes is progressively increased along its length to increase the total resistance path between the p and n electrode along their length. This prevents the problem current crowding at the end of the p-electrodes observed in the conventional art when the distance between n and p electrodes is kept constant. This in turn increases the current uniformity through the active region of the chip, increasing the efficiency of the chip and reducing the forward operating voltage.

A seventh, non-limiting aspect of the invention may include a nitride-based LED with a transparent current spreading in contact with a p-type layer. The p-pad is then located in the center of the opposite edge of the LED chip, at the edge of the chip. The n-branch electrode extends from the n-pad towards the p-pad up the center line of the chip. Two p-branch electrodes extend from the p-pad towards the opposite edge along both sides of the central branch n-electrode. In this embodiment, the same principle as the previous embodiment is used, whereby the resistance between the n and p electrodes is varied along their length. In this embodiment, this is achieved by progressively increasing the width of the n-electrode along its length. This means the area of the n-electrode in contact with the n-layer increases per unit length, reducing the contact resistance per unit length for current passing from the n-electrode into the n-layer. This embodiment has all the advantages of the previous embodiment.

### BRIEF DESCRIPTION OF THE DRAWINGS

FIG. 1 is a cross-sectional view of a conventional nitride-based light emitting device (LED).

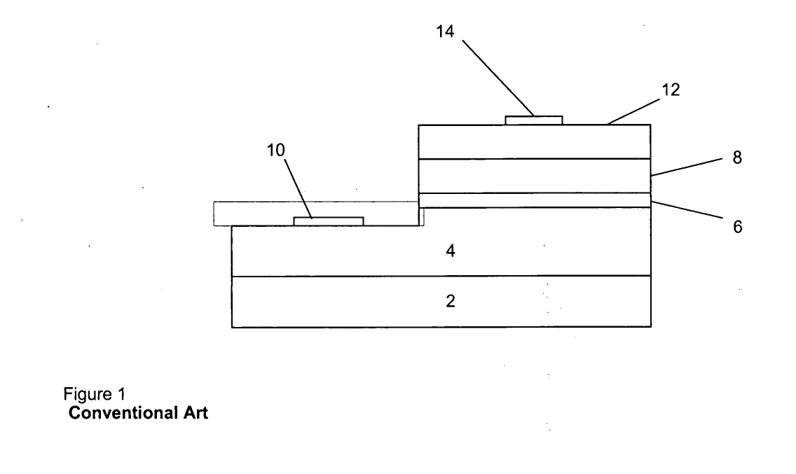

FIG. 2 is a plan view of a conventional branch electrode design of a nitride-based LED.

FIG. 3 is a cross-sectional view of a branch electrode on a semiconductor layer according to a non-limiting embodiment of the present invention.

FIG. 4 is a plan view of a branch electrode design of a nitride-based LED according to a first, non-limiting embodiment of the present invention.

FIG. 5 is a graph showing operating current against forward operating voltage for two nitride-based LEDs: one with an electrode design according to the first, non-limiting embodiment; and one with a conventional electrode design.

FIG. 6 is a plan view of a branch electrode design of a nitride-based LED according to a second, non-limiting embodiment of the present invention.

FIG. 7 is a plan view of a branch electrode design of a nitride-based LED according to a third, non-limiting embodiment of the present invention.

FIG. 8 is a plan view of a branch electrode design of a nitride-based LED according to a fourth, non-limiting embodiment of the present invention.

FIG. 9 is a plan view of a branch electrode design of a nitride-based LED according to a fifth, non-limiting embodiment of the present invention.

FIG. 10 is a plan view of a branch electrode design of a nitride-based LED according to a sixth, non-limiting embodiment of the present invention.

FIG. 11 is a plan view of a branch electrode design of a nitride-based LED according to a seventh, non-limiting embodiment of the present invention.

### DETAILED DESCRIPTION OF THE EXAMPLE EMBODIMENTS

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

A p-branch electrode may provide a relatively low resistance path for current to more easily spread over the area of the chip and into the p-type layer or current spreading layer (if one is used), with which the p electrode is in electrical contact with. An n-branch electrode may provide a lower resistance path for current to more easily spread over the area of the chip and into the n-type layer, with which the n electrode is in electrical contact with. The desired electrical properties of the p-branch electrode material are that it has a relatively high electrical conductivity and makes a suitable electrical contact with the p-layer. Similarly, the desired properties of the n-branch electrode material are that it has a relatively high electrical conductivity and makes a suitable electrical contact with the p-layer or current spreading layer (if one is used). To fulfill these requirements, the branch electrodes may be made of metal or multiple layers of different metals.

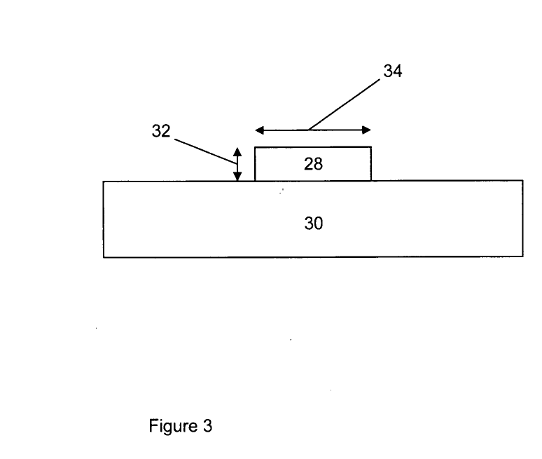

FIG. 3 shows the cross-section of a branch electrode 28 formed on an LED layer 30. For a p-branch electrode, the relevant LED layer 30 would be a p-type layer or current spreading layer. On the other hand, for an n-branch electrode, the relevant LED layer 30 would be an n-type layer. The width 34 and height 32 of the branch electrodes are a trade-off between electrical performance (which generally increases with increased width 34 and height 32) and optical performance and cost (both of which decrease with increased width 34 and height 32). The overall resistance of the branch electrode 28 decreases with width 34 and height 32, and the contact resistance between the branch electrode 28 and the semiconductor layer 30 with which it is in contact with also decreases with the width 34 of the electrode. In contrast, the material cost of the branch electrode 28 also increases with width 34 and height 32, as does the optical absorption, which reduces the overall efficiency of the LED. A p-branch electrode may have a width in the range of about 1 to 25 microns (e.g., between about 3 and 10 microns). A n-branch electrode may also have a width in the range of about 1 to 25 microns (e.g., between about 3 to 10 microns). The height of both branch electrodes may be in the range of about 100 to 4000 nm (e.g., within the range of about 250 to 2000 nm).

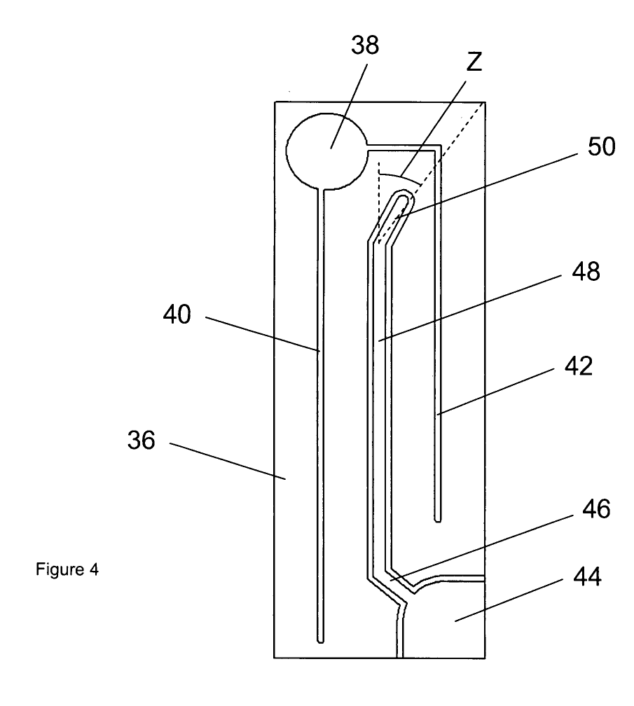

FIG. 4 shows one embodiment of the invention, a nitride-based LED having a transparent current spreading layer 36 on which there is formed a p-contact pad 38 in one corner of the device. Extending from the p-contact pad 38 are two p-branch electrodes 40 and 42. The first p-branch electrode 40 extends parallel to the longer edge of the chip. The second p-branch electrode 42 extends parallel to the shorter edge of the chip and then turns to run parallel to the longer edge of the chip. The n-pad 44 is formed on the opposite corner to the p-pad 38. The n-branch electrode extends diagonally from the n-pad 44 for a short section 46 until it is along the center-line of the chip, from where it extends for a long section 48 in the direction of the longest edge of the chip. The length of the long section 48 of the n-branch electrode, expressed as a fraction of the total length of the chip, is between about 0.05 and 0.7 (e.g., between about 0.1 and 0.6). The end section 50 of the n-branch electrode is inclined towards the corner opposite both the n and p contact pads 38 and 44 and nearest the n-branch electrode. Z indicates the angle of inclination to the vertical axis of the line from the point defined by the start of the inclined end section 50 of the n-branch electrode, and the top right hand corner of the LED chip. The angle of inclination to the vertical axis of the inclined end section 50 of the n-branch electrode may be between about Z−35 and Z+15 degrees (e.g., between Z−25 and Z+5 degrees). The length of the inclined end section 50 of the n-branch electrode, expressed as a fraction of the distance between the end of the straight section of n-branch electrode and the point of intersection between the inclined section of n-electrode and the p-electrode, may be between about 0.05 and 0.8 (e.g., between about 0.1 and 0.6).

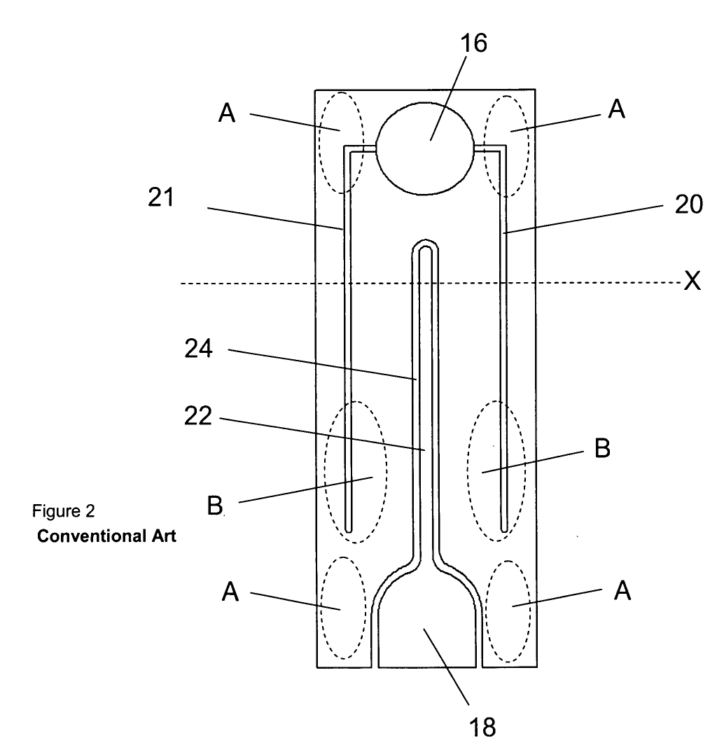

Electrical simulations have been performed for an example of this first embodiment. The chip size for the simulation was 200×560 microns. The n and p pads both have at least the area of circle of radius 45 microns, which is to enable an external electrical wire connection to be made to the chip. The p-branch electrode has a width of 6 microns and a height of 1000 nm, and is in electrical contact with the current spreading layer, which in turn is in electrical contact with the p-layer. The n branch electrode has a width of 12 microns and a height of 1000 nm, and is in electrical contact with the n-layer. In order to form the n-branch electrode and the n-pad in electrical contact with the n-type layer it is necessary to etch away part of the current spreading layer, p-type layer, and active region to reveal the surface of the n-type layer. This can be done by any standard suitable etching technique known to those ordinarily skilled in the art. The area which has been etched includes a 6 micron border around the edge of the n-contact pad and n-branch electrode. This border allows for an alignment error when the n-electrode and n-contact pad are formed on the n-layer surface which has been revealed by the etching. Electrical simulations were performed of this electrode design to predict the operating voltage at different currents, and the uniformity of the current density through the active region. As a numerical measure of the current uniformity, the ratio of the maximum current density to the average current density can be used. The lower this ratio, the more uniform the current is spread through the active region and the less current crowding exists. A perfectly uniform current distribution would give a ratio of 1. For comparison, the conventional electrode design shown in FIG. 2 has also been simulated with the same dimensions as the present example. The current uniformity ratio calculated from the simulation results at an operating current of 100 mA for the conventional art was 1.58, and for the present example 1.27. This shows a significant improvement in the current uniformity through the active region for the present invention over the conventional art.

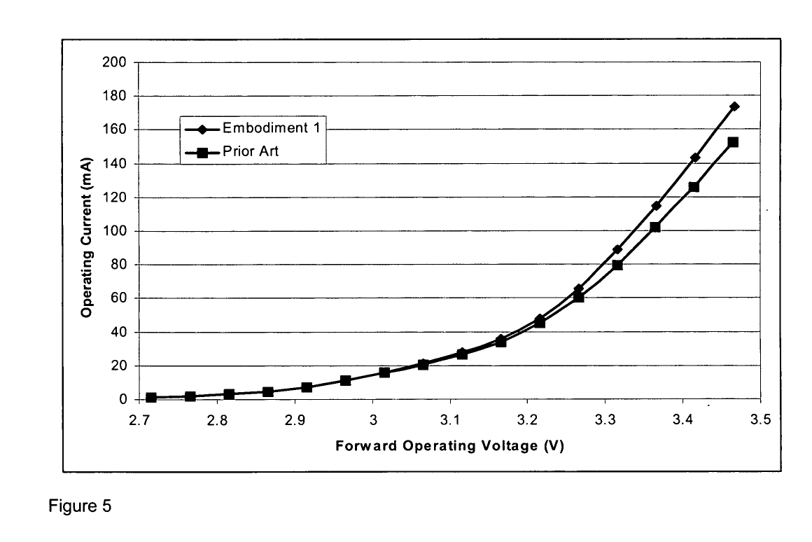

FIG. 5 also shows a graph of forward voltage against operating current for two nitride LEDs: one with an electrode design according to an example embodiment of the present embodiment, and one with a conventional electrode design as shown in FIG. 2. Both LEDs have the same chip and electrode dimensions. This shows a clear reduction in forward operating voltage for the LED with the electrode design according to the example embodiment of the present embodiment over the LED with a conventional electrode design.

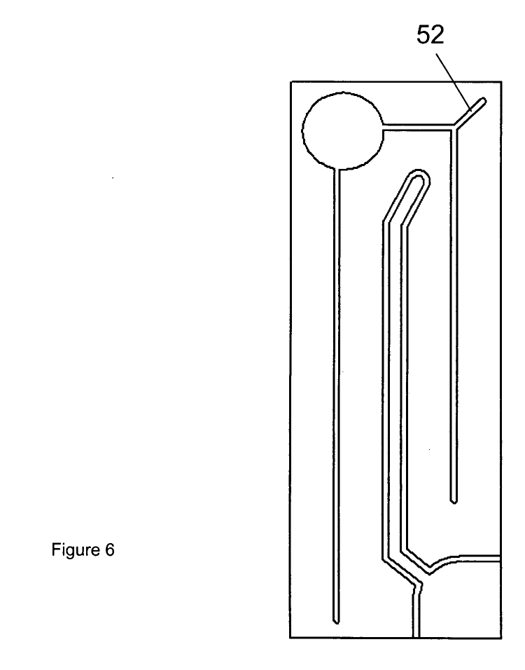

Another embodiment of the invention, shown in FIG. 6, is a nitride-based LED with a current spreading layer and an electrode design as described in the first embodiment with the addition of a corner extension 52 which extends from the second p-branch electrode in the corner of the chip where the second p branch electrode turns after running parallel to the shorter edge of the chip to run parallel to the longer edge. This extra branch extends in a direction which is generally towards the corner of the chip and its length, as expressed as a fraction of the distance to the corner of the chip should be between about 0.1 and 0.8 (e.g., between about 0.2 and 0.6). This extra p-branch electrode (corner extension) 52 further increases the current density through the active region in this corner of the chip, by reducing the resistance path for current travelling from the p-electrode branch to the n-electrode branch through the active region in this corner.

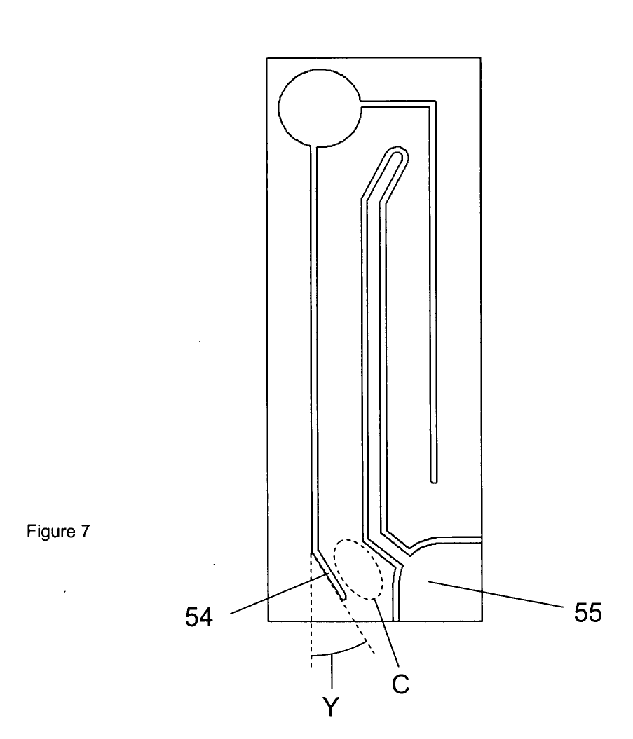

Another embodiment of the invention, as shown in FIG. 7, is a nitride-based LED with a current spreading layer and an electrode design as described in the first embodiment with the addition that, the end section 54 of the first p-branch electrode is inclined towards the n-pad 55. The first p-branch electrode extends from the p-pad parallel to the longer edge of the chip up to a point which expressed as a fraction of the length of the chip is between about 0.4 and 0.95 (e.g., between about 0.5 and 0.9). The end section 54 of the p-branch electrode is then inclined towards the n-pad 55 at an angle Y of between about 5 and 80 degrees (e.g., between about 20 and 65 degrees). The end section 54 of the first p-branch electrode extends at this angle Y until a point which expressed as a fraction of the length of the chip is between about 0.55 and 0.99 (e.g., between about 0.65 and 0.95). The advantage of the inclined end section 54 of the first p-electrode branch is to prevent an area of low-current density (area is marked C on FIG. 6) from forming between the n-pad 55 and the end of the first p-electrode 54. It has the effect of reducing the total resistance path for current to flow between the n and p electrodes through this area of the active region.

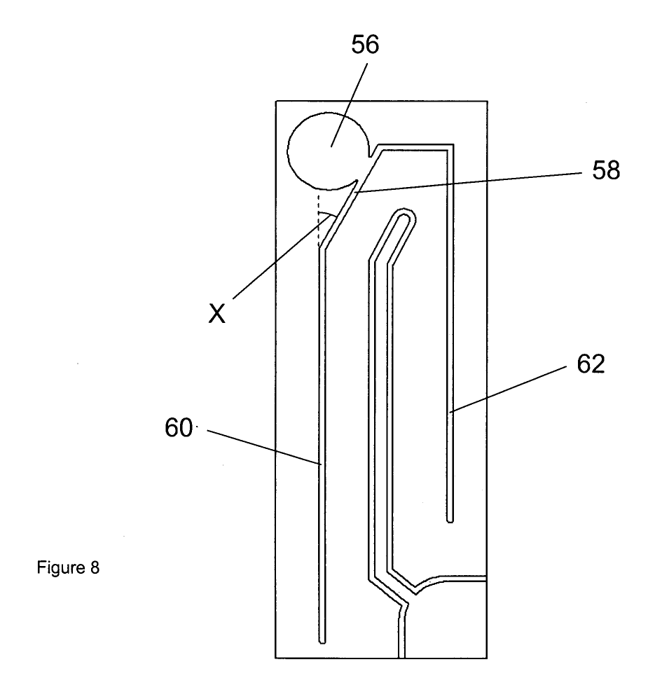

Another embodiment of the invention, as shown in FIG. 8, is a nitride-based LED with a current spreading layer and an electrode design as described in the first embodiment with the addition that instead of the p-branch electrodes 60 and 62 extending from the p-pad 56 separately, a common connector 58 connects the p-pad 56 to both p-branch electrodes 60 and 62. The angle X of this connector 58 to the vertical axis of the chip may be between about 5 and 75 degrees (e.g., between about 10 and 50 degrees). The position of the connector 58 may be defined by the fact that it tangentially intersects with the edge of the p-pad 56. The endpoints of the connector 58 are the intersections with the first and second p-branch electrodes 60 and 62. This intersection points also act as the starting points for the first and second p-branch electrodes 60 and 62. The advantage of this embodiment is to reduce the forward operating voltage of the LED and to improve the overall light extraction efficiency of the led by reducing the current density through the active region directly underneath the p-pad 56.

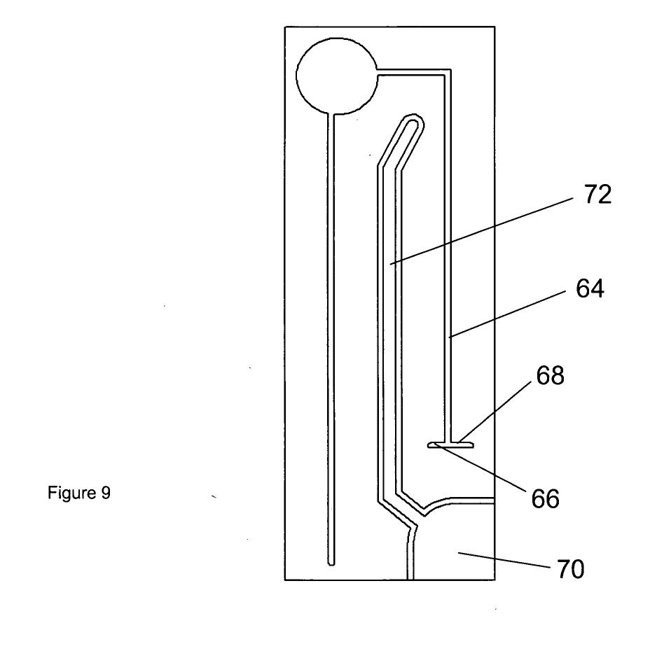

Another embodiment of the invention, as shown in FIG. 9, is a nitride-based LED with a current spreading layer and an electrode design as described in the first embodiment with the addition that at the end of the second p-branch electrode 64, the branch splits in two, and the two new branches (end extensions) 66 and 68, extend from this vertex in generally opposite directions. The angle of inclination between each one of the new branches and the original branch may be between about 45 and 135 degrees (e.g., between about 80 and 100 degrees). The length of the new branch 68 which extends towards the edge of the chip should have a length, which expressed as a fraction of the width of the n-pad 70, may be between about 0.05 and 0.45 (e.g., between about 0.1 and 0.3). The length of the new branch 66 which extends towards the n-branch electrode 72 should have a length, which expressed as a fraction of the distance to the edge of the p-layer next to the n-electrode 72, may be between about 0.05 and 0.45 (e.g., between about 0.1 and 0.3).

The purpose of this extra feature is to make the first and second end extensions 66 and 68 more parallel to the edge of the n-pad 70 that it faces. Without this feature current would flow from all points along the edge of the n-pad 70 to the single point at the end of the second p-branch electrode 64, creating current crowding at the end of the second p-branch electrode 64. With the feature, the first and second end extensions 66 and 68 are generally parallel to the n-pad 70, so the resistive path between opposite points on the n-pad 70 and the p-branch electrode 64 is approximately equal. This causes the current flowing out of the n-pad 70 to flow into a larger area of the first and second end extensions 66 and 68, thereby reducing the current crowding effect in this area of the chip. This reduces the forward operating voltage and makes chip operate more efficiently.

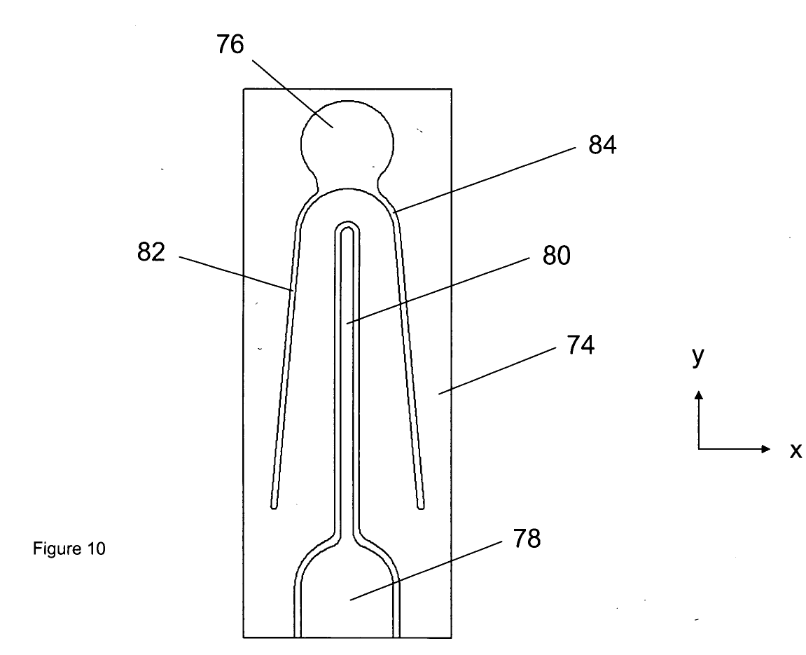

Another embodiment of the invention, as shown in FIG. 10, is a nitride-based LED with a transparent current spreading layer 74 on which there is formed a p-pad 76 at one end of the device in the center of the shortest edge. The n-pad 78 is then located in the center of the opposite edge of the LED chip, at the edge of the chip. The n-branch electrode 80 extends from the n-pad 78 towards the p-pad 76 up the center line of the chip. The first and second p-branch electrodes 82 and 84 extend from the p-pad 76 towards the opposite edge along both sides of the n-branch electrode 80. The distance between the n-branch electrode 80 and the p-branch electrodes 82, 84 is progressively increased along its length to increase the total resistance patch between the n-branch electrode 80 and the p-branch electrodes 82, 84 with regard to an increase in proximity to the n-pad 78. The distance between the n-branch electrode 80 and the p-branch electrodes 82, 84 may be symmetrical, such that the distance from each point along the n branch electrode 80 to each point along the length of each p-branch electrode 82, 84 is the same. Assuming the direction along which the n-branch electrode 80 extends from the n-pad 78 to be the y direction, and the direction orthogonal to this to be the x direction, the separation between two single points on the n-branch electrode 80 and the p-branch electrodes 82, 84 with the same y value varies progressively from between about 0.05 w and 0.35 w to between about 0.25 w and 0.5 w (e.g., between 0.15 w and 0.25 w to between 0.35 w and 0.45 w), where w is the full width of the LED chip. This prevents the problem of current crowding at the end of the p-electrodes observed in the conventional art and increases the current uniformity through the active region of the chip.

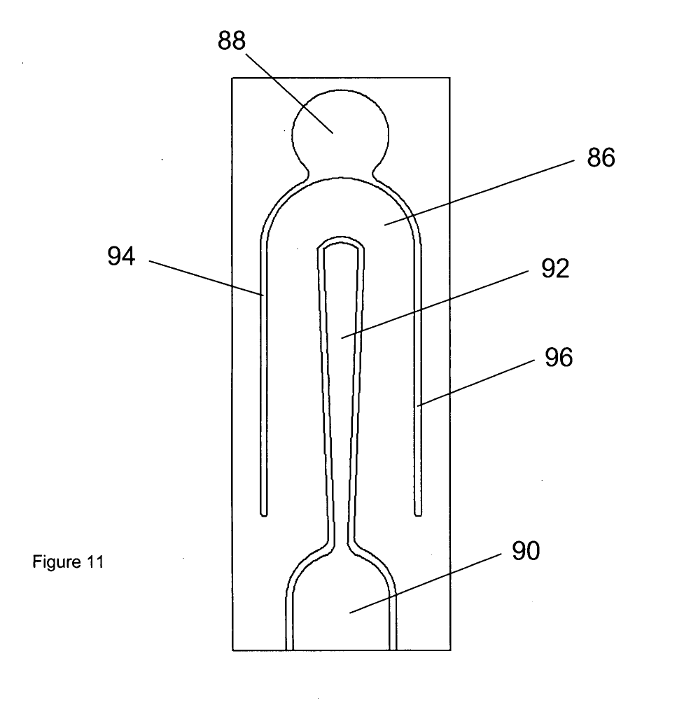

Another embodiment of this invention, as shown in FIG. 11, is a nitride-based LED with a transparent current spreading layer 86 on which there is formed a p-pad 88 at one end of the device in the center of the shortest edge. The n-pad 90 is then located in the center of the opposite edge of the LED chip, at the edge of the chip. The n-branch electrode 92 extends from the n-pad 90 towards the p-pad 88 up the center line of the chip. Two p-branch electrodes 94, 96 extend from the p-pad 88 towards the opposite edge along both sides of the n-branch electrode 92. The width of the n-branch electrode 92 is progressively increased along its length with regard to a decreased proximity to the n-pad 90, such that the end of the n-branch electrode 92 has a width between about 1.2 and 4 times its initial width when it protrudes from the n-pad 90 (e.g., between about 1.5 and 2.5 times its initial width). This means the area of the n-branch electrode 92 in contact with the n-layer increases per unit length, thereby reducing the contact resistance per unit length for current passing from the n-branch electrode 92 into the n-layer. This embodiment has all the advantages of the previous embodiment.

While example embodiments of the invention have been disclosed herein, it should be understood that other variations may be possible. Such variations are not to be regarded as a departure from the spirit and scope of the present invention, and all such modifications as would be obvious to one skilled in the art are intended to be included within the scope of the following claims.

1. A nitride light emitting device comprising:
a p-pad and an n-pad disposed on opposite ends of the device;
a first p-branch electrode and a second p-branch electrode extending from the p-pad toward the n-pad, the first p-branch electrode extending along a length of the device, the second p-branch electrode including a bent portion so as to extend along a width and length of the device; and
an n-branch electrode extending from the n-pad toward the p-pad, a distal end of the n-branch electrode being angled toward the bent portion of the second p-branch electrode.

2. The device of claim 1, wherein the p-pad and the n-pad are disposed on diagonal corners of the device.

3. The device of claim 1, wherein the n-branch electrode extends between the first p-branch electrode and the second p-branch electrode.

4. The device of claim 1, wherein a proximal end of the n-branch electrode extends at an angle toward a center line of the device.

5. The device of claim 1, wherein a majority of the n-branch electrode extends along a center line of the device.

6. The device of claim 1, further comprising:
a corner extension extending outward from the bent portion of the second p-branch electrode toward a corner adjacent to the diagonal corners of the device.

7. The device of claim 1, wherein a distal end of the first p-branch electrode is angled toward the n-pad.

8. The device of claim 1, wherein the first p-branch electrode and second p-branch electrode contact the p-pad at a common point.

9. The device of claim 1, further comprising:
a common connector that connects the first p-branch electrode and the second p-branch electrode to the p-pad.

10. The device of claim 1, further comprising:
a first end extension and a second end extension extending from a distal end of the second p-branch electrode.

11. The device of claim 10, wherein the first end extension and second end extension extend in opposite directions.

12. The device of claim 1, further comprising:
a transparent current spreading layer, the p-pad being disposed on the transparent current spreading layer.

13. A nitride light emitting device comprising:
a p-pad and an n-pad disposed on opposite ends of the device;
a first p-branch electrode and a second p-branch electrode extending from the p-pad toward the n-pad; and
an n-branch electrode extending from the n-pad toward the p-pad, a distance between the n-branch electrode and the first and second p-branch electrodes being relatively increased in relation to a relative increase in proximity to the n-pad.

14. The device of claim 13, wherein the n-branch electrode extends between the first p-branch electrode and the second p-branch electrode.

15. The device of claim 13, wherein the p-pad and n-pad are centered about a center line of the device.

16. The device of claim 13, wherein the n-branch electrode extends along a center line of the device.

17. The device of claim 13, wherein the device is symmetrical about a longitudinal axis of the device.

18. The device of claim 13, wherein the first and second p-branch electrodes diverge during the extension toward the n-pad.

19. The device of claim 18, wherein a width of the n-branch electrode remains constant.

20. The device of claim 13, wherein a width of the n-branch electrode increases with proximity to the p-pad.

21. The device of claim 20, wherein a majority of the first and second p-branch electrodes extend in parallel.
